(19) United States
(12) Patent Application Publication
(10) Pub. No.: US 2024/0096950 A1
(43) Pub. Date: Mar. 21, 2024

(54) RESISTIVE PRESSURE-SENSITIVE COMPOSITE AND METHOD OF MAKING THE SAME

(71) Applicant: RET Equipment Inc., Fremont, CA (US)

(72) Inventors: Yu Qiu, Los Angeles, CA (US); Frank Hu, Cupertino, CA (US)

(21) Appl. No.: 17/946,420

(22) Filed: Sep. 16, 2022

(51) Int. Cl. H01L 29/06; B82Y 30/00; B82Y 40/00

(52) U.S. Cl. CPC H01L 29/0673; B82Y 30/00; B82Y 40/00

(57) ABSTRACT

A transparent anisotropically oriented nanowire-polymer resistive pressure-sensitive composite film, its method of making, and a transparent resistive pressure sensor are disclosed. The transparent nanowire-polymer resistive pressure-sensitive composite film may include a single layer of conductive nanowires uniformly distributed in a transparent dielectric polymer matrix and oriented along the thickness direction of the transparent nanowire-polymer resistive pressure-sensitive composite film. The method of making the nanowire-polymer resistive pressure-sensitive composite film may include a directional assembly of conductive nanowires through a liquid-air interface in a template-free fashion by a spray-induced orientation method.

### TECHNICAL FIELD

The present disclosure relates to the technical field of nanomaterial composites, and particularly relates to a transparent nanowire-polymer resistive pressure-sensitive composite film, a method of making the transparent nanowire-polymer resistive pressure-sensitive composite film, and a transparent resistive pressure sensor comprising the transparent nanowire-polymer resistive pressure-sensitive composite film.

### BACKGROUND

Display touchscreen devices have been widely used in various electronic products such as appliances, televisions, computers, monitors, and portable electronic devices such as mobile phones, smart phones, smart watches, tablet computers, electronic books, portable game consoles, smart controllers, etc. Usually, the display touchscreen device employs a pressure sensor to detect a location of a touch and/or a press to further initiate or prosecute a function. Most recently, a pressure sensor with a three-dimension touch pressure sensing feature has attracted extensive attentions.

The pressure sensor typically generates an electrical signal related to an applied force to measure the applied force in a specific area such as a location where the applied force is exerted and/or the amount of the applied force upon the detected location. One type of the most common pressure sensors is based on a conductive pressure-sensitive composite to achieve the pressure response. The conductive pressure-sensitive composite relies on tunneling current between conductive particles embedded in an elastic polymer medium to detect pressure such as touch pressure. When the pressure-sensitive composite is compressed by a mechanical load, for example by a finger or a stylus, the electrical properties of the pressure-sensitive composite, such as resistance or resistivity, will change in response to an applied pressure. However, the practical application of the pressure-sensitive composite requires the composite to be completely and uniformly compressed in its f functional region, thus requiring a large force to achieve a proper function. As a result, the polymer-conductive particle composite lacks the ability to measure the local pressure precisely and accurately and is limited to sensing the existence and difference of the overall force exerted on the composite. In addition, most conductive pressure-sensitive composites lack high optical transparency and/or long-term durability under repeated deformation, which limits their applications in visual display products.

In order to improve the optical transparency of pressure-sensitive composites, recently, conductive nanoparticles have been increasingly used in elastic polymer media to achieve high conductivity at a low concentration. However, in practical applications, the thickness of the pressure-sensitive composite material still needs to reach a certain level to achieve a large range of pressure sensing. This causes light to be scattered by conductive nanoparticles in the direction of the material's thickness, which reduces the optical transparency of the pressure-sensitive composites.

In polymer-conductive nanoparticle composites, controlling the arrangement of conductive nanoparticles in the polymer media may improve the performance and uniformity of the composites. Therefore, several assembly techniques, such as an electric field-directed assembly, a Langmuir-Blodgett deposition, a capillary printing, or a directional fluid assembly, etc., have been developed to control the assembly and planar alignment of nanoparticles. However, these methods are limited in their ability to produce large-area thin films with uniformly aligned nanoparticles, i.e., they are limited to small-area components and have no or less control over the thickness-wise alignment.

Therefore, there is a need for improved pressure-sensitive composites and pressure sensing devices.

### SUMMARY

The present disclosure provides a transparent anisotropically oriented nanowire-polymer resistive pressure-sensitive composite film, a method of making the transparent anisotropically oriented nanowire-polymer resistive pressure-sensitive composite film, and a transparent resistive pressure sensor comprising the transparent anisotropically oriented nanowire-polymer resistive pressure-sensitive composite film. The transparent resistive pressure sensor provided in the present disclosure may not only detect a location of an applied pressure but al so quantitatively measure the amount of pressure applied on the sensor and is optically transparent to visible light.

According to a first aspect of the present disclosure, there is provided a method of making a nanowire-polymer resistive pressure-sensitive composite film comprising a transparent polymer dielectric matrix and a conductive one-dimensional nanomaterial uniformly distributed in the transparent polymer dielectric matrix and oriented substantially in a thickness direction of the nanowire-polymer resistive pressure-sensitive composite film, the method including:
providing a synthetic substrate coated with a release layer thereon and providing a polymer precursor solution comprising a liquid precursor of the transparent polymer dielectric matrix and optionally a first volatile solvent;
coating the polymer precursor solution on the release layer at room temperature to obtain a liquid precursor film on the release layer by using the polymer precursor solution;
heating the liquid precursor film to a first temperature, wherein the first temperature is lower than a boiling point of the liquid precursor of the transparent polymer dielectric matrix and a polymerization temperature of the liquid precursor of the transparent polymer dielectric matrix if the liquid precursor of the transparent polymer dielectric matrix is thermally polymerizable;
spraying vertically and uniformly a conductive nanowire suspension comprising a conductive one-dimensional nanomaterial and a second volatile solvent onto the liquid precursor film to obtain the liquid precursor film embedded with the conductive one-dimensional nanomaterial that is oriented substantially in a thickness direction of the liquid precursor film, wherein a boiling point of the second volatile solvent is lower than the first temperature;
in-situ polymerizing and curing the liquid precursor film embedded with the conductive one-dimensional nanomaterial by heating the liquid precursor film embedded with the conductive one-dimensional nanomaterial to a second temperature or irradiating the liquid precursor film embedded with the conductive one-dimensional nanomaterial with UV light to obtain a cured liquid precursor film embedded with the conductive one-dimensional nanomaterial, wherein the second temperature is higher than the polymerization temperature of the liquid precursor of the transparent polymer dielectric matrix if the liquid precursor of the transparent polymer dielectric matrix is thermally polymerizable; and
removing the cured liquid precursor film embedded with the conductive one-dimensional nanomaterial from the synthetic substrate to obtain the nanowire-polymer resistive pressure-sensitive composite film comprising the conductive one-dimensional nanomaterial oriented substantially in a thickness direction of the nanowire-polymer resistive pressure-sensitive composite film.

According to a second aspect of the present disclosure, there is provided a transparent nanowire-polymer resistive pressure-sensitive composite film comprising a transparent polymer dielectric matrix and a conductive one-dimensional nanomaterial uniformly distributed in the transparent polymer dielectric matrix and oriented substantially in a thickness direction of the transparent nanowire-polymer resistive pressure-sensitive composite film. The conductive one-dimensional nanomaterial may include conductive nanowires selected from the group consisting of a metal nanowire, a conductive polymer nanowire, a ceramic conductive nanowire, a carbon nanowire, a single walled carbon nanotube, a multi-walled carbon nanotube, and a mixture thereof. The conductive nanowires are uniformly distributed in the transparent polymer dielectric matrix, oriented substantially in a thickness direction of the transparent nanowire-polymer resistive pressure-sensitive composite film, and partially exposed on a first surface and/or a second surface of the transparent polymer dielectric matrix to form non cross-talking and dispersed conductive units, where the first surface and second surface of the transparent polymer dielectric matrix are opposite and parallel to each other and are orthogonal to the thickness direction of the transparent nanowire-polymer resistive pressure-sensitive composite film, and each conductive unit comprises at least one through electrically conductive channel extending from the first surface to the second surface of the transparent polymer dielectric matrix through one single conductive nanowire or multiple conductive nanowires.

According to a third aspect of the present disclosure, there is provided a transparent resistive pressure sensor comprising the transparent nanowire-polymer resistive pressure-sensitive composite film according to the second aspect of the present disclosure.

Therefore, the present disclosure discloses a method of making a transparent anisotropically oriented nanowire-polymer resistive pressure-sensitive composite film, and its application in a transparent resistive pressure sensor. The transparent nanowire-polymer resistive pressure-sensitive composite film disclosed in the present disclosure includes a single layer of conductive nanowires uniformly distributed in a transparent dielectric polymer matrix and oriented along the thickness direction of the transparent nanowire-polymer resistive pressure-sensitive composite film. Due to the anisotropic physical properties of the conductive one-dimensional nanowires, the nanowire-polymer resistive pressure-sensitive composite film has the characteristics of pressure sensitivity, high optical transparency, and long-term durability. The method of preparing the nanowire-polymer resistive pressure-sensitive composite film includes a directional assembly of conductive nanowires through a liquid-air interface in a template-free fashion by a spray-induced orientation method. Thus, the disclosed method provides an economical and fast way to produce a nanowire density tunable, nanowire highly oriented thickness-wise, and large-area nanowire-polymer resistive pressure-sensitive composite film. The subject matters of present disclosure may be used in conjunction with conventional touch panel electronics to precisely detect a location where a force is applied and accurately measure the amount of the force applied locally, they may also be configured to recognize multiple touch locations simultaneously.

It should be understood that the above general description and the following detailed description are only exemplary and explanatory and are not restrictive of the present disclosure.

### BRIEF DESCRIPTION OF THE DRAWINGS

In order to explain the technical features of embodiments of the present disclosure more clearly, the drawings used in the present disclosure are briefly introduced as follow. Obviously, the drawings in the following description are some exemplary embodiments of the present disclosure. Ordinary person skilled in the art may obtain other drawings and features based on these disclosed drawings without inventive efforts.

FIG. 1 is a flowchart illustrating a method of making a nanowire-polymer resistive pressure-sensitive composite film according to some embodiments of the present disclosure.

FIG. 2 illustrates a schematic diagram of a method of making a nanowire-polymer resistive pressure-sensitive composite film according to some embodiments of the present disclosure.

FIG. 3 illustrates schematic diagrams of a method of making a nanowire-polymer resistive pressure-sensitive composite film under different spraying conditions according to some embodiments of the present disclosure.

FIG. 4 illustrates schematic diagrams of a method of making a nanowire-polymer resistive pressure-sensitive composite film according to some embodiments of the present disclosure.

FIG. 5 illustrates a schematic perspective view of a transparent nanowire-polymer resistive pressure-sensitive composite film according to some embodiments of the present disclosure.

FIG. 6 illustrates a partial enlarged cross-sectional view of a transparent nanowire-polymer resistive pressure-sensitive composite film according to some embodiments of the present disclosure.

FIG. 7 illustrates schematic cross-section views of a transparent resistive pressure sensor system operating under different amount of compressing force according to some embodiments of the present disclosure.

Like symbols and reference numerals in the various drawings indicate like elements.

### DETAILED DESCRIPTION

The technical solutions and technical features encompassed in the present disclosure will now be described more fully herein in conjunction with the accompanying drawings, in which exemplary embodiments of the disclosure are illustrated. It should be understood that the embodiments disclosed herein are merely examples, each incorporating certain benefits of the present disclosure. Various modifications and alterations may be made to the following examples within the scope of the present disclosure by persons skilled in the art. It should be understood that one or more steps within a method may be executed in different order (or concurrently) or separately without altering the principles of the disclosure. Features of the different embodiments may be combined in different ways to reach yet further embodiments. Accordingly, the scope of the disclosure is to be understood from the entirety of the present disclosure in view of, but not limited to, the embodiments described herein.

Unless otherwise defined, all technical and scientific terms used in the present disclosure have their ordinary meaning as commonly understood by those skilled in the technical field of the present disclosure. The terms used herein are only for the purpose of describing specific embodiments and are not intended to limit of the disclosure. As used in this disclosure and the appended claims, the singular forms “a,” “an,” and “the” are intended to include the plural forms as well, unless the context clearly indicates otherwise. It should also be understood that the term “and/or” as used herein refers to and encompasses any or all possible combinations of one or more associated listed items.

The term “monomer” used herein means a relatively low molecular weight material (i.e., having a molecular weight less than about 500 g/mole) having one or more radically polymerizable groups. When a monomer molecule reacts with other monomer molecules, a larger polymer chain or network is formed in a polymerization process.

The term “oligomer” used herein means a relatively intermediate molecular weight material having a molecular weight in a range from about 500 g/mole to about 10,000 g/mole, which may consist of a few repeating units that are derived from a monomer.

The term “prepolymer” used herein refers to a monomer or system of monomers that have been reacted to an intermediate molecular mass state and can be further reacted with reactive groups to a fully cured, high molecular weight state.

The term “(meth)acrylate” with respect to a monomer, oligomer or prepolymer means a vinyl-functional alkyl ester formed as the reaction product of an alcohol with an acrylic or a methacrylic acid.

The term “one-dimensional nanomaterial” used herein refers to a nanomaterial having a nanostructure in the form of a nanowire with the diameter of the order of a nanometer. In the present disclosure, “one-dimensional nanomaterial” and “nanowire” may be interchangeable. The one-dimensional nanomaterial typically exhibits a large aspect ratio (length-to-width ratio), such as an aspect ratio of 10 or more, 20 or more, 30 or more, 40 or more, 50 or more, 100 or more, 200 or more, 500 or more, or 1000 or more. In some embodiments of the present disclosure, a conductive one-dimensional nanomaterial has an aspect ratio of 10 or more, 20 or more, 30 or more, 40 or more, 50 or more, 100 or more, 200 or more, 500 or more, or 1000 or more.

The term “polymerization temperature” used herein refers to the temperature of a reaction mixture during a polymerization reaction. The method for measuring the polymerization temperature may be appropriately selected from any known methods in the art, such as measuring a change in the viscosity of the reaction mixture. The polymerization may be appropriately determined based on factors such a precursor, a solvent, and a polymerization initiator. The polymerization temperature is preferably 80° C. to 200° C., more preferably 100° C. to 200° C., furthermore preferably 100° C. to 180° C., and particularly preferably 100° C. to 150° C.

The term “about” used herein shall generally mean within 20 percent, preferably within 10 percent, and more preferably within 5 percent of a given value or property. Unless otherwise clear from the context, all numerical values provided herein are modified by the term “about.”

The term “optically transparent” used herein when applied to an object means that the object is clear, and light may pass through the object to be perceived by human eyes. Thus, light in the visible portion of the spectrum may pass through the transparent resistive pressure sensor of the present disclosure to be perceived by human eyes.

It should be noted that in the instant disclosure, relational terms such as “first” and “second”, etc. are used herein merely to distinguish one entity or operation from another entity or operation without necessarily requiring or implying any such actual relationship or order between such entities or operations. The terms “comprise/comprising”, “include/including”, “has/have/having” or any other variants thereof are intended to cover non-exclusive inclusion, so that a process, method, article, or device that includes a series of elements includes not only those elements, but also other elements that are not explicitly listed, or also includes elements inherent to such processes, methods, articles, or equipment. If there are no more restrictions, the element defined by the phrase, such as “comprising a . . . ”, “including a . . . ” does not exclude the presence of additional identical elements in the process, method, article, or equipment that includes the element.

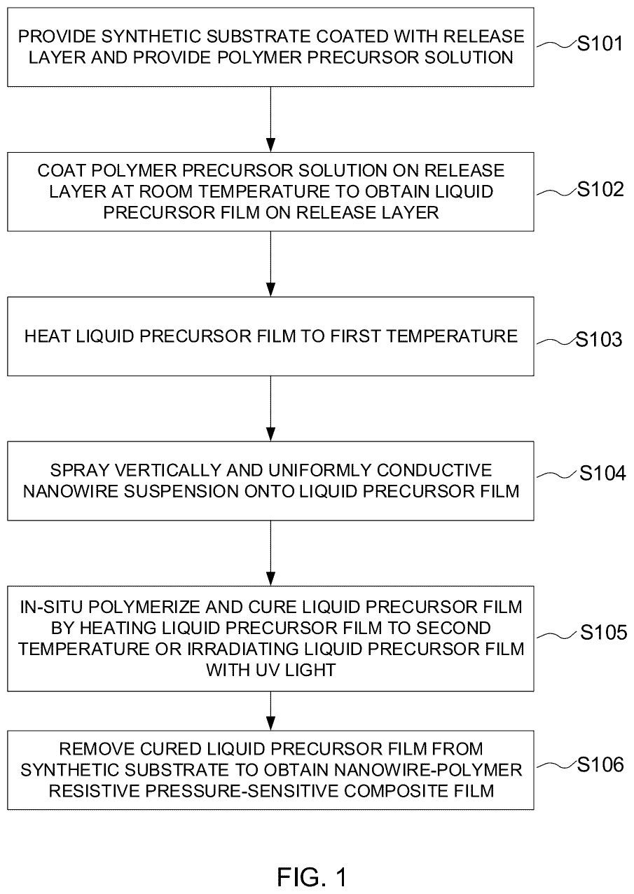

Please refer to FIG. 1, which is a flowchart illustrating a method of making a nanowire-polymer resistive pressure-sensitive composite film according to some embodiments of the present disclosure. The nanowire-polymer resistive pressure-sensitive composite film may include a transparent polymer dielectric matrix and a conductive one-dimensional nanomaterial uniformly distributed in the transparent polymer dielectric matrix and oriented substantially in a thickness direction of the nanowire-polymer resistive pressure-sensitive composite film. As shown in FIG. 1, the method may include steps S101-S106.

Step S101 may include providing a synthetic substrate coated with a release layer and providing a polymer precursor solution.

The synthetic substrate is coated with a release layer thereon to facilitate obtaining the nanowire-polymer resistive pressure-sensitive composite film. The suitable synthetic substrate may include, but is not limited to, a glass substrate, a metal substrate, a silicon wafer substrate, or a polymeric substrate such as a polyethylene terephthalate (PET), a polyethylene naphthalate (PEN), a colorless polyimide (CPI), a polycarbonate (PC), a polymethylmethacrylate (PMMA), a polystyrene (PS), a polyethersulfone (PES), a polynorbornene (PNB), etc. In one embodiment, the synthetic substrate is a glass panel. In another embodiment, the synthetic substrate is a silicon wafer. The release layer is not particularly limited in the present disclosure, which may be formed by applying a coating liquid containing a resin, a releasing agent, or a wax to the synthetic substrate.

The polymer precursor solution may include a liquid precursor of the transparent polymer dielectric matrix. The liquid precursor may include a monomer, an oligomer, or a prepolymer of an acrylate, a methacrylate, an acrylic acid, a methacrylic acid, an acrylamide, a methacrylamide, a methylstyrene, a siloxane, a silicone ether, an isocyanate, an epoxy compound, or a mixture thereof. In some embodiments, the liquid precursor is selected from the group consisting of an acrylate, a methacrylate, an acrylic acid, a methacrylic acid, an acrylamide, a methacrylamide, a methylstyrene, a siloxane, a silicone ether, an isocyanate, an epoxy, an oligomer thereof, a prepolymer thereof, and a mixture thereof. In some embodiments, the polymer precursor solution may further include a thermal initiator. In some embodiments, the polymer precursor solution may further include a photoinitiator.

In some embodiments, the polymer precursor solution may further include a first volatile solvent. The first volatile solvent may include one or more of water, a volatile alcohol, a volatile ether, tetrahydrofuran, dioxane, a volatile ketone, or a volatile ester. The suitable volatile alcohol may include, but is not limited to, methanol, ethanol, propanol, iso-propanol, n-butanol, tert-butanol, iso-butanol, or a mixture thereof. The suitable volatile ether may include, but is not limited to, dimethyl ether, methyl ethyl ether, diethyl ether, 2-methoxy-2-methylpropane, or a mixture thereof. The suitable volatile ketone may include, but is not limited to, acetone, methylethylketone, cyclohexanone, cyclopentanone, etc. The suitable volatile ester may include, but is not limited to, ethyl acetate, ethyl propanoate, propyl methanoate, propyl ethanoate, methyl butanoate, etc.

Step S102 may include coating the polymer precursor solution on the release layer at room temperature to obtain a liquid precursor film on the release layer.

The polymer precursor solution is coated on the release layer at room temperature to obtain a liquid precursor film on the release layer by a thin film coating technique such as spin coating, Meyer rod coating, doctor blade coating, spray coating, screen printing, ink jet printing, roll coating, etc., which is not particularly limited in the present disclosure.

The thickness of the liquid precursor film is in a range of 0.1 microns-100 microns, preferably 1 micron-100 microns, more preferably 1 micron-50 microns, furthermore preferably 1 micron-20 microns, particularly preferably 1 micron-10 microns.

Step S103 may include heating the liquid precursor film to a first temperature.

The liquid precursor film with the synthetic substrate is heated to a first temperature by a heat source such as a heating plate. The heat source is not particularly limited in the present disclosure. The first temperature is lower than a boiling point of the liquid precursor of the transparent polymer dielectric matrix and lower than a polymerization temperature of the liquid precursor of the transparent polymer dielectric matrix if the liquid precursor of the transparent polymer dielectric matrix is thermally polymerizable. In some embodiments, the first temperature may be in a range of 80° C. to 120° C., 80° C. to 110° C., or 80° C. to 100° C. A viscosity of the liquid precursor is in a range of 0.5-2000 cP at the first temperature.

Step S104 may include spraying vertically and uniformly a conductive nanowire suspension onto the liquid precursor film.

The conductive nanowire suspension that may include the conductive one-dimensional nanomaterial and a second volatile solvent is vertically and uniformly sprayed onto the liquid precursor film to obtain the liquid precursor film embedded with the conductive one-dimensional material that is oriented substantially in a thickness direction of the liquid precursor film by using a spray device comprising at least one spray nozzle. During the spraying, the at least one spray nozzle is maintained perpendicular to a first surface of the liquid precursor film that faces the at least one spray nozzle. The size of the at least one spray nozzle is in a range of 0.01 mm-1 mm, 0.02 mm-1 mm, 0.03 mm-1 mm, 0.04 mm-1 mm, 0.05 mm-1 mm, 0.06 mm-1 mm, 0.07 mm-1 mm, 0.08 mm-1 mm, 0.09 mm-1 mm, 0.1 mm-1 mm, 0.2 mm-1 mm, 0.3 mm-1 mm, 0.4 mm-1 mm, 0.5 mm-1 mm, 0.6 mm-1 mm, 0.7 mm-1 mm, 0.8 mm-1 mm, or 0.9 mm-1 mm, or within any range defined between any two of the foregoing values, such as 0.3 mm-0.5 mm. In one embodiment, the size of the at least one spray nozzle is about 0.2 mm. In another embodiment, the size of the at least one spray nozzle is about 0.5 mm.

The conductive one-dimensional nanomaterial may comprise conductive nanowires selected from the group consisting of a metal nanowire, a conductive polymer nanowire, a ceramic conductive nanowire, a carbon nanowire, a single walled carbon nanotube, a multi-walled carbon nanotube, and a mixture thereof. In some embodiments, the conductive one-dimensional nanomaterial is a metal nanowire. The metal nanowire may include, but is not limited to, a silver nanowire (Ag nanowire), a copper nanowire, a gold nanowire, a nickel nanowire, a platinum nanowire, a stainless steel nanowire, or a mixture thereof. In one embodiment, the conductive one-dimensional nanomaterial is a silver nanowire. In some embodiments, the conductive one-dimensional nanomaterial is a single walled carbon nanotube. In some embodiments, the conductive one-dimensional nanomaterial is a multi-walled carbon nanotube. In some embodiments, the conductive one-dimensional nanomaterial is a mixture of a single walled carbon nanotube and a multi-walled carbon nanotube.

A diameter of the conductive nanowire suitable for the conductive one-dimensional nanomaterial is in a range of 1 nm-100 nm. In some embodiments, a diameter of the conductive nanowire suitable for the conductive one-dimensional nanomaterial is in a range 1 nm-10 nm. In some embodiments, a diameter of the conductive nanowire suitable for the conductive one-dimensional nanomaterial is in a range 10 nm-50 nm. In some embodiments, a diameter of the conductive nanowire suitable for the conductive one-dimensional nanomaterial is in a range 50 nm-100 nm. A length of the conductive nanowire suitable for the conductive one-dimensional nanomaterial is in a range of 100% to 200% of the thickness of the liquid precursor film.

The second volatile solvent may include one or more of water, a volatile alcohol, a volatile ether, tetrahydrofuran, dioxane, a volatile ketone, or a volatile ester. The suitable volatile alcohol may include, but is not limited to, methanol, ethanol, propanol, iso-propanol, n-butanol, tert-butanol, iso-butanol, or a mixture thereof. The suitable volatile ether may include, but is not limited to, dimethyl ether, methyl ethyl ether, diethyl ether, 2-methoxy-2-methylpropane, or a mixture thereof. The suitable volatile ketone may include, but is not limited to, acetone, methylethylketone, cyclohexanone, cyclopentanone, etc. The suitable volatile ester may include, but is not limited to, ethyl acetate, ethyl propanoate, propyl methanoate, propyl ethanoate, methyl butanoate, etc. The second volatile solvent may or may not be the same as the first volatile solvent. A boiling point of the second volatile solvent is lower than the first temperature.

A mass ratio of the conductive one-dimensional nanomaterial to the second volatile solvent is in a range of 0.005 wt %-0.05 wt %, 0.006 wt %-0.05 wt %, 0.007 wt %-0.05 wt %, 0.008 wt %-0.05 wt %, 0.009 wt %-0.05 wt %, 0.01 wt %-0.05 wt %, 0.02 wt %-0.05 wt %, 0.03 wt %-0.05 wt %, or 0.04 wt %-0.05 wt %, or within any range defined between any two of the foregoing values, such as 0.01 wt %-0.03 wt %. In one embodiment, the mass ratio of the conductive one-dimensional nanomaterial to the second volatile solvent is about 0.01 wt %. In another embodiment, the mass ratio of the conductive one-dimensional nanomaterial to the second volatile solvent is about 0.04 wt %. In some embodiments, the mass ratio of silver nanowires to the second volatile solvent in in a range of 0.005 wt %-0.05 wt %. In some embodiments, the mass ratio of single-walled carbon nanotubes to the second volatile solvent in in a range of 0.005 wt %-0.05 wt %. In some embodiments, the mass ratio of multi-walled carbon nanotubes to the second volatile solvent in in a range of 0.005 wt %-0.05 wt %.

In the process of the spraying, when the synthetic substrate is large or multiple rounds of spraying is needed, the spray device may be controlled to move parallel to the first surface of the liquid precursor film in a predetermined direction or pattern while a spraying direction of the at least one spray nozzle of the spray device is maintained to be perpendicular to the first surface of the liquid precursor film, in such a way, the conductive nanowire suspension is uniformly sprayed onto the entire first surface of the liquid precursor film. Since the liquid precursor film is at the first temperature, which is higher than the boiling point of the second volatile solvent, when the conductive nanowire suspension comprising conductive nanowires and the second volatile solvent just contacts or has not yet contacted the first surface of the liquid precursor film, the second volatile solvent has been volatilized or evaporated. Due to the spray-induced orientation, at least a portion of the conductive nanowires are substantially perpendicular to the first surface of the liquid precursor film along the spraying direction, and due to the spray-induced momentum, at least a portion of the conductive nanowires may penetrate into the interior of the liquid precursor film and from the first surface of the liquid precursor film to a second surface of the liquid precursor film opposite and parallel to the first surface of the liquid precursor in a direction substantially perpendicular to the first surface of the liquid precursor film, resulting in the liquid precursor film embedded with the conductive one-dimensional material that is oriented substantially in a thickness direction of the liquid precursor film. The term “substantially perpendicular to” used herein means an included angle between the longitudinal axis of the conductive one-dimensional nanomaterial and a reference surface such as the first surface of the liquid precursor film is in a range of 70-90 degrees. In other words, the longitudinal axis of the conductive one-dimensional nanomaterial is oriented within 0-20 degrees of the surface normal of the first surface of the liquid precursor film. In some embodiments, at least 60% of conductive nanowires embedded in the liquid precursor film are oriented substantially perpendicular to the first surface of the liquid precursor film. In some embodiments, at least 70% of conductive nanowires embedded in the liquid precursor film are oriented substantially perpendicular to the first surface of the liquid precursor film. In one preferred embodiment, at least 80% of conductive nanowires embedded in the liquid precursor film are oriented substantially perpendicular to the first surface of the liquid precursor film.

The viscosity of the liquid precursor is in a range of 0.5-2000 cP at the first temperature. If the viscosity of the liquid precursor is too high, such as higher than 2000 cP, the conductive nanowires cannot penetrate into the liquid precursor film due to insufficient spray-induced momentum; if the viscosity of the liquid precursor is too low, such as lower than 0.5 cP, the liquid precursor film cannot keep the conductive nanowires penetrating into the liquid precursor film in position, resulting in displacement of the conductive nanowires before the liquid precursor film is cured. Thus, the spraying may further comprise adjusting a spraying distance between the at least one spray nozzle of the spray device and the first surface of the liquid precursor film, a size of the at least one spray nozzle, a spraying angle, and a spraying pressure. The spraying distance is in a range of 1 cm-20 cm, the size of the at least one spray nozzle is in a range of 0.01 mm-1 mm, the spraying angle is equal to or less than 40 degrees, and the spraying pressure is in a range of 14.7 psi-80 psi.

Step S105 may include in-situ polymerizing and curing the liquid precursor film by heating the liquid precursor film to a second temperature or irradiating the liquid precursor film with UV light.

In some embodiments, the liquid precursor film embedded with the conductive one-dimensional material may be in-situ polymerized and cured by heating the liquid precursor film embedded with the conductive one-dimensional material to a second temperature to obtain a cured liquid precursor film embedded with the conductive one-dimensional material when the liquid precursor of the transparent polymer dielectric matrix is thermally polymerizable. The second temperature is higher than the polymerization temperature of the liquid precursor of the transparent polymer dielectric matrix. In some embodiments, the liquid precursor film may include a thermal initiator. In some embodiments, the thermal initiation may include, but is not limited to, benzol peroxide or 2,2′-azobis(2-methylpropionitrile), etc.

In some embodiments, the liquid precursor film embedded with the conductive one-dimensional material may be in-situ polymerized and cured by irradiating the liquid precursor film embedded with the conductive one-dimensional material with UV light to obtain a cured liquid precursor film embedded with the conductive one-dimensional material. In some embodiments, the liquid precursor film may further comprise a photoinitiator. The photoinitiator may be acetophenone-based, vinyl acrylate-based, benzoin-based, or thioxanthenone-based, etc. which is not particularly limited in the present disclosure.

The cured liquid precursor film forms the transparent polymer dielectric matrix of the nanowire-polymer resistive pressure-sensitive composite film. Since the in-situ polymerizing and curing does not change the orientation of conductive nanowires embedded in the cured liquid precursor film, the conductive nanowires embedded in the transparent polymer dielectric matrix of the nanowire-polymer resistive pressure-sensitive composite film are oriented substantially in a thickness direction of the nanowire-polymer resistive pressure-sensitive composite film. The conductive nanowire oriented substantially in the thickness direction of the nanowire-polymer resistive pressure-sensitive composite film means the longitudinal axis of the conductive nanowire embedded in the nanowire-polymer resistive pressure-sensitive composite film is substantially parallel to the thickness direction of the nanowire-polymer resistive pressure-sensitive composite film, and the included angle between the longitudinal axis of the conductive nanowire embedded in the nanowire-polymer resistive pressure-sensitive composite film and the thickness direction of the nanowire-polymer resistive pressure-sensitive composite film is in a range of 0-20 degrees. In some embodiments, at least 60% of conductive nanowires embedded in the nanowire-polymer resistive pressure-sensitive composite film are oriented substantially in the thickness direction of the nanowire-polymer resistive pressure-sensitive composite film. In some embodiments, at least 70% of conductive nanowires embedded in the nanowire-polymer resistive pressure-sensitive composite film are oriented substantially in the thickness direction of the nanowire-polymer resistive pressure-sensitive composite film. In one preferred embodiment, at least 80% of conductive nanowires embedded in the nanowire-polymer resistive pressure-sensitive composite film are oriented substantially in the thickness direction of the nanowire-polymer resistive pressure-sensitive composite film.

The transparent polymer dielectric matrix formed of the cured liquid precursor film has a storage modulus of 10 kPa-10 GPa, 100 kPa-10 GPa 1 MPa-10 GPa, 10 MPa-10 GPa, 100 MPa-10 GPa, 500 MPa-10 GPa, 1 GPa-10 GPa, 2 GPa-10 GPa, 3 GPa-10 GPa, 4 GPa-10 GPa, or 5 GPa-10 GPa, or any range defined between any two of the foregoing values, such as 1 MPa-500 MPa, at an ambient temperature. In some preferred embodiments, the transparent polymer dielectric matrix has a storage modulus in a range of 100 kPa-100 MPa at an ambient temperature.

Step S106 may include removing the cured liquid precursor film from the synthetic substrate to obtain the nanowire-polymer resistive pressure-sensitive composite film.

The cured liquid precursor film embedded with the conductive one-dimensional material is then removed from the synthetic substrate to obtain the nanowire-polymer resistive pressure-sensitive composite film comprising the conductive one-dimensional nanomaterial oriented substantially in the thickness direction of the nanowire-polymer resistive pressure-sensitive composite film. In some embodiments, the nanowire-polymer resistive pressure-sensitive composite film is highly optically transparent in the visible spectrum.

The conductive nanowires embedded in the transparent polymer dielectric matrix are uniformly distributed in the transparent polymer dielectric matrix and partially exposed on a first surface and/or a second surface opposite the first surface of the transparent polymer dielectric matrix to form non cross-talking and dispersed conductive units, where the first surface and second surface of the transparent polymer dielectric matrix are opposite and parallel to each other and are orthogonal to the thickness direction of the transparent nanowire-polymer resistive pressure-sensitive composite film, and each conductive unit comprises at least one through electrically conductive channel extending from the first surface to the second surface of the transparent polymer dielectric matrix through one single conductive nanowire or multiple conductive nanowires. The term “non cross-talking” used herein means that there is no electrical contact between two adjacent conductive units. The conductive units have enough space between each other to ensure that the adjacent conductive units in the same area are isolated by the transparent polymer dielectric medium. Thus, the resistance is low within the conductive units and extremely high between the conductive units, in other words, the nanowire-polymer resistive pressure-sensitive composite film has extremely high resistance across the first surface and across the second surface of the transparent polymer dielectric matrix, but low resistance within the conductive units across the transparent polymer dielectric matrix, i.e., in a thickness direction of the nanowire-polymer resistive pressure-sensitive composite film. In some embodiments, the conductive units on the first/second surfaces of the transparent polymer dielectric matrix are present at a density from about 1 to 10⁵ conductive units per square microns, preferably from about 10 to 10⁵ conductive units per square microns, more preferably from about 10² to 10⁵ conductive units per square microns, even more preferably from about 10³ to 10⁵ conductive units per square microns. The obtained the nanowire-polymer resistive pressure-sensitive composite film may be used in a pressure sensor or other electronic devices.

The thickness of the nanowire-polymer resistive pressure-sensitive composite film is in a range of 0.1 microns-100 microns, preferably 1 micron-100 microns, more preferably 1 micron-50 microns, furthermore preferably 1 micron-20 microns, particularly preferably 1 micron-10 microns.

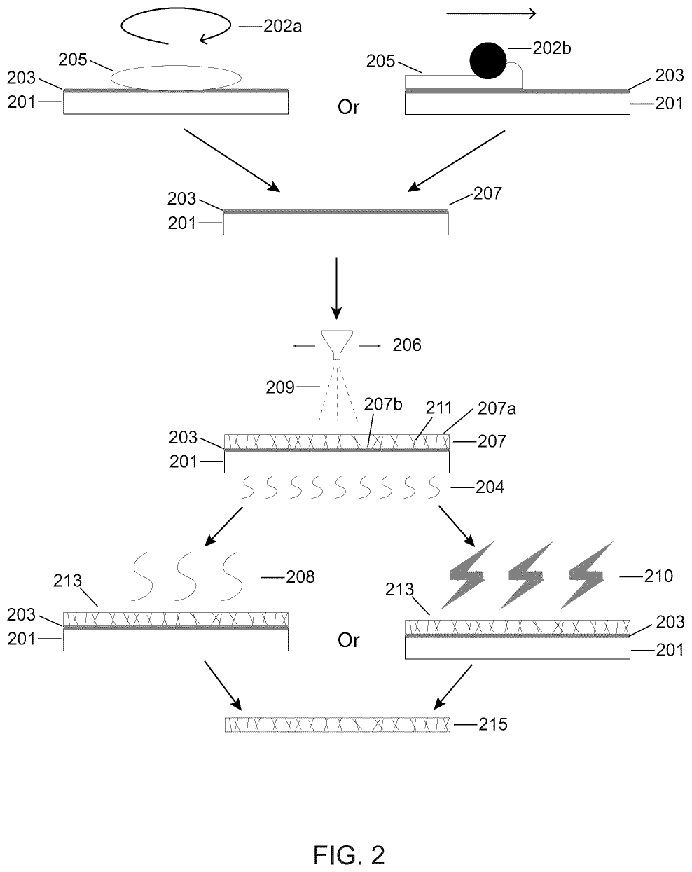

Hereinafter, the method of making the nanowire-polymer resistive pressure-sensitive composite film according to the example embodiments of the inventive concept as described above will be further described with reference to FIGS. 2 to 4. It should be noted that the features and characteristics of each element and/or operation described below may be further referred to the detail description of its corresponding counterpart described above.

Please refer to FIG. 2, which illustrates a schematic diagram of a method of making a nanowire-polymer resistive pressure-sensitive composite film according to some embodiments of the present disclosure. The nanowire-polymer resistive pressure-sensitive composite film comprises a transparent polymer dielectric matrix and a conductive one-dimensional nanomaterial uniformly distributed in the transparent polymer dielectric matrix and oriented substantially in a thickness direction of the nanowire-polymer resistive pressure-sensitive composite film.

As shown in FIG. 2, according to step S101, a synthetic substrate 201 coated with a release layer 203 thereon and a polymer precursor solution 205 are provided. The polymer precursor solution 205 may include a liquid precursor of the transparent polymer dielectric matrix and optionally a first volatile solvent.

Then, as described in step S102, the polymer precursor solution 205 is coated on the release layer 203 at room temperature to obtain a liquid precursor film 207 on the release layer 203 by a thin film coating technique. For example, in some embodiments, the polymer precursor solution 205 may be coated on the release layer 203 at room temperature to obtain a liquid precursor film 207 on the release layer 203 by a spin-coating 202a. In other embodiments, the polymer precursor solution 205 may be coated on the release layer 203 at room temperature to obtain a liquid precursor film 207 on the release layer 203 by a Meyer rod coating 202b.

Then, as described in step S103, the liquid precursor film 207 is heated to a first temperature by heating 204. The heating 204 may be achieved by using a heating source such as a heating plate, which is not particularly limited in the present disclosure. The first temperature is lower than a boiling point of the liquid precursor of the transparent polymer dielectric matrix and a polymerization temperature of the liquid precursor of the transparent polymer dielectric matrix if the liquid precursor of the transparent polymer dielectric matrix is thermally polymerizable.

Then, as described in step 104, a conductive nanowire suspension 209 is sprayed vertically and uniformly onto the heated liquid precursor film 207 by using a spray device 206 comprising at least one spray nozzle. During the spraying, the at least one spray nozzle is maintained perpendicular to a first surface 207a of the liquid precursor film 207 that faces the at least one spray nozzle. The conductive nanowire suspension may include the conductive one-dimensional nanomaterial and a second volatile solvent. The conductive one-dimensional nanomaterial may comprise conductive nanowires 211 selected from the group consisting of a metal nanowire, a conductive polymer nanowire, a ceramic conductive nanowire, a carbon nanowire, a single walled carbon nanotube, a multi-walled carbon nanotube, and a mixture thereof. A boiling point of the second volatile solvent is lower than the first temperature.

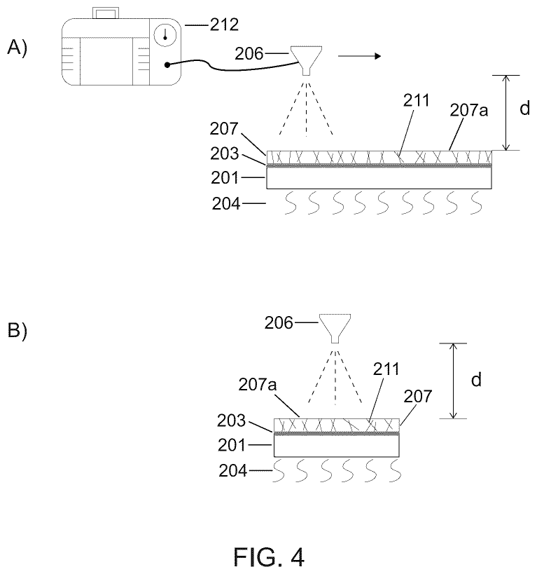

When the synthetic substrate 201 is large, as shown in the panel A of FIG. 4, or multiple rounds of spraying is needed, under a desired spraying pressure 212 and a desired spraying distance d, the spray device 206 may be controlled to move parallel to the first surface 207a of the liquid precursor film 207 in a predetermined direction or pattern while the spraying direction of the at least one spray nozzle of the spray device is maintained to be perpendicular to the first surface 207a of the liquid precursor film 207, so that the conductive nanowire suspension 209 is uniformly sprayed onto the entire first surface 207a of the liquid precursor film 207. When the synthetic substrate 201 is small, as shown in the panel B of FIG. 4, under a desired spraying pressure and a desired spraying distance d, the spray device 206 may be kept still relative to the first surface 207a of the liquid precursor film 207, and the conductive nanowire suspension 209 is uniformly sprayed onto the entire first surface 207a of the liquid precursor film 207.

Since the liquid precursor film is 207 at the first temperature, which is higher than the boiling point of the second volatile solvent, when the conductive nanowire suspension comprising conductive nanowires 211 and the second volatile solvent just contacts or has not yet contacted the first surface 207a of the liquid precursor film 207, the second volatile solvent has been volatilized or evaporated. Due to the spray-induced orientation, at least a portion of the conductive nanowires 211 are substantially perpendicular to the first surface 207a of the liquid precursor film 207 along a spraying direction, and due to the spray-induced momentum, at least a portion of the conductive nanowires 211 may penetrate into the interior of the liquid precursor film 207 and from the first surface 207a of the liquid precursor film 207 to a second surface 207b of the liquid precursor film 207, which is opposite and parallel to the first surface 207a of the liquid precursor film 207, in a direction substantially perpendicular to the first surface 207a of the liquid precursor film 207, resulting in the liquid precursor film 207 embedded with the conductive one-dimensional material, i.e., the conductive nanowire 211, that is oriented substantially in a thickness direction of the liquid precursor film 207. The term “substantially perpendicular to” used herein means an included angle between the longitudinal axis of the conductive one-dimensional nanomaterial and a reference surface such as the first surface 207a of the liquid precursor film 207 is in a range of 70-90 degrees. In other words, the longitudinal axis of the conductive one-dimensional nanomaterial is oriented within 0-20 degrees of the surface normal of the first surface 207a of the liquid precursor film 207. In some embodiments, at least 60% of conductive nanowires 211 embedded in the liquid precursor film 207 are oriented substantially perpendicular to the first surface 207a of the liquid precursor film 207. In some embodiments, at least 70% of conductive nanowires 211 embedded in the liquid precursor film 207 are oriented substantially perpendicular to the first surface 207a of the liquid precursor film 207. In one preferred embodiment, at least 80% of conductive nanowires 211 embedded in the liquid precursor film 207 are oriented substantially perpendicular to the first surface 207a of the liquid precursor film 207.

The viscosity of the liquid precursor is in a range of 0.5-2000 cP at the first temperature. If the viscosity of the liquid precursor is too high, such as higher than 2000 cP, the conductive nanowires 211 may not be able to penetrate into the liquid precursor film 207 due to insufficient spray-induced momentum; if the viscosity of the liquid precursor is too low, such as lower than 0.5 cP, the liquid precursor film 207 cannot keep the conductive nanowires 211 penetrating into the liquid precursor film 207 in position, resulting in displacement of the conductive nanowires before the liquid precursor film 207 is cured.

Thus, the spraying may further comprise adjusting a spraying distance between the at least one spray nozzle of the spray device 206 and the first surface 207a of the liquid precursor film 207, a size of the at least one spray nozzle, a spraying angle, and a spraying pressure based upon the viscosity of the liquid precursor and the property of the conductive nanowire suspension 209; as such, the orientation, density, and momentum of the sprayed conductive nanowires may be controlled. The smaller the spraying distance between the at least one spray nozzle of the spray device 206 and the first surface 207a of the liquid precursor film 207, the smaller the size of the at least one spray nozzle, and the greater the spraying pressure of the spray device 206, the greater the momentum of the sprayed conductive nanowires and the greater the density of the sprayed conductive nanowires.

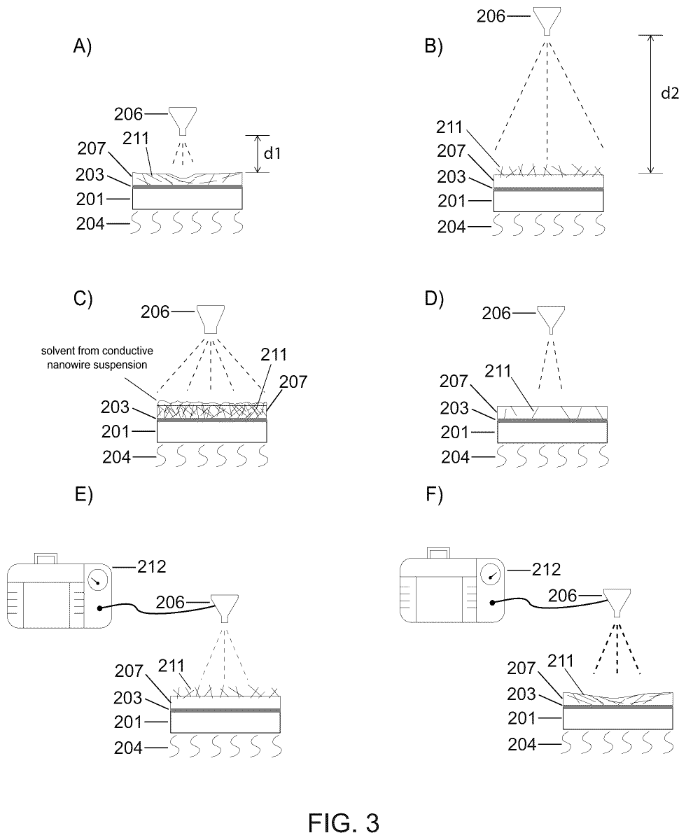

Referring to the panel A of FIG. 3, if the spraying distance between the at least one spray nozzle of the spray device 206 and the first surface of the liquid precursor film 207 facing the at least one spray nozzle is too short, the second volatile solvent in the conductive nanowire suspension 209 will not volatilize completely, and some of the second volatile solvent will remain on the first surface of the liquid precursor film 207, resulting in the aggregation of conductive nanowires and affecting the subsequent polymerization of the liquid precursor film to form the polymer dielectric matrix. Further, the orientation of conductive nanowires embedded in the liquid precursor film 207 may be disturbed by the spraying; referring to the panel B of FIG. 3, if the spraying distance between the at least one spray nozzle of the spray device 206 and the first surface of the liquid precursor film 207 is too far away, it will lead to conductive nanowires 211 insufficient momentum to penetrate into the liquid precursor film 207. A preferred spraying distance, d, between the at least one spray nozzle of the spray device 206 and the first surface of the liquid precursor film 207 is in a range of 1 cm-20 cm.

Referring to the panel C of FIG. 3, if the size of the at least one spray nozzle of the spray device 206 is too large, too much conductive nanowire suspension will be sprayed, and the second volatile solvent of the conductive nanowire suspension 209 will not be able to volatilize in time, and the density of conductive nanowires will be too large, so that the adjacent conductive units of the resulted nanowire-polymer resistive pressure-sensitive composite film in the same area will be connected to each other; referring to the panel D of FIG. 3, if the size of the at least one spray nozzle of the spray device 206 is too small, the at least one spray nozzle of the spray device 206 will be extremely easily blocked, and the production efficiency is reduced. A preferred size of the at least one spray nozzle of the spray device 206 is in a range of 0.01 mm-1 mm

Referring to the panel E of FIG. 3, if the spraying pressure 212 of the spray device 206 is too low, the conductive nanowires 211 will not have sufficient momentum to penetrate into the liquid precursor film 207; referring to the panel F of FIG. 3, if the spraying pressure 212 of the spray device 206 is too high, the arrangement and orientation of the conductive nanowires 211 in the liquid precursor film 207 will be destroyed, A preferred spraying pressure of the spray device 206 is in a range of 14.7 psi-80 psi.

Referring back to FIG. 2, after the conductive nanowire suspension 209 is vertically and uniformly sprayed onto the heated liquid precursor film 207, and the liquid precursor film 207 embedded with the conductive one-dimensional material (i.e., the conductive nanowires 211) that is oriented substantially in a thickness direction of the liquid precursor film 207 is formed on the release layer 203, as described in step S105, the liquid precursor film 207 embedded with the conductive one-dimensional material is then polymerized and cured by heating 208 the liquid precursor film 207 embedded with the conductive one-dimensional material to a second temperature if the liquid precursor of the transparent polymer dielectric matrix is thermally polymerizable or irradiating 210 with UV light to obtain a cured liquid precursor film 213 embedded with the conductive one-dimensional material. And then, as described in step S106, The cured liquid precursor film 213 embedded with the conductive one-dimensional material is removed from the synthetic substrate 201 to obtain the nanowire-polymer resistive pressure-sensitive composite film 215 comprising the conductive one-dimensional nanomaterial oriented substantially in the thickness direction of the nanowire-polymer resistive pressure-sensitive composite film 215. In some embodiments, the nanowire-polymer resistive pressure-sensitive composite film 215 is highly optically transparent in the visible spectrum.

The cured liquid precursor film 213 forms the transparent polymer dielectric matrix of the nanowire-polymer resistive pressure-sensitive composite film 215. The transparent polymer dielectric matrix formed of the cured liquid precursor film has a storage modulus of 10 kPa-10 GPa, 100 kPa-10 GPa 1 MPa-10 GPa, 10 MPa-10 GPa, 100 MPa-10 GPa, 500 MPa-10 GPa, 1 GPa-10 GPa, 2 GPa-10 GPa, 3 GPa-10 GPa, 4 GPa-10 GPa, or 5 GPa-10 GPa, or any range defined between any two of the foregoing values, such as 1 MPa-500 MPa, at an ambient temperature. In some preferred embodiments, the transparent polymer dielectric matrix has a storage modulus in a range of 100 kPa-100 MPa at an ambient temperature. Since the in-situ polymerizing and curing does not change the orientation of conductive nanowires 211 embedded in the cured liquid precursor film 213, the conductive nanowires 211 embedded in the transparent polymer dielectric matrix of the nanowire-polymer resistive pressure-sensitive composite film 215 are oriented substantially in a thickness direction of the nanowire-polymer resistive pressure-sensitive composite film 215. The conductive nanowire 211 oriented substantially in the thickness direction of the nanowire-polymer resistive pressure-sensitive composite film 215 means the longitudinal axis of the conductive nanowire 211 embedded in the nanowire-polymer resistive pressure-sensitive composite film 215 is substantially parallel to the thickness direction of the nanowire-polymer resistive pressure-sensitive composite film 215, and the included angle between the longitudinal axis of the conductive nanowire 211 embedded in the nanowire-polymer resistive pressure-sensitive composite film 215 and the thickness direction of the nanowire-polymer resistive pressure-sensitive composite film 215 is in a range of 0-20 degrees. In some embodiments, at least 60% of conductive nanowires 211 embedded in the nanowire-polymer resistive pressure-sensitive composite film 215 are oriented substantially in the thickness direction of the nanowire-polymer resistive pressure-sensitive composite film 215. In some embodiments, at least 70% of conductive nanowires 211 embedded in the nanowire-polymer resistive pressure-sensitive composite film 215 are oriented substantially in the thickness direction of the nanowire-polymer resistive pressure-sensitive composite film 215. In one preferred embodiment, at least 80% of conductive nanowires 211 embedded in the nanowire-polymer resistive pressure-sensitive composite film 215 are oriented substantially in the thickness direction of the nanowire-polymer resistive pressure-sensitive composite film 215.

The thickness of the nanowire-polymer resistive pressure-sensitive composite film 215 is in a range of 0.1 microns-100 microns, preferably 1 micron-100 microns, more preferably 1 micron-50 microns, furthermore preferably 1 micron-20 microns, particularly preferably 1 micron-10 microns.

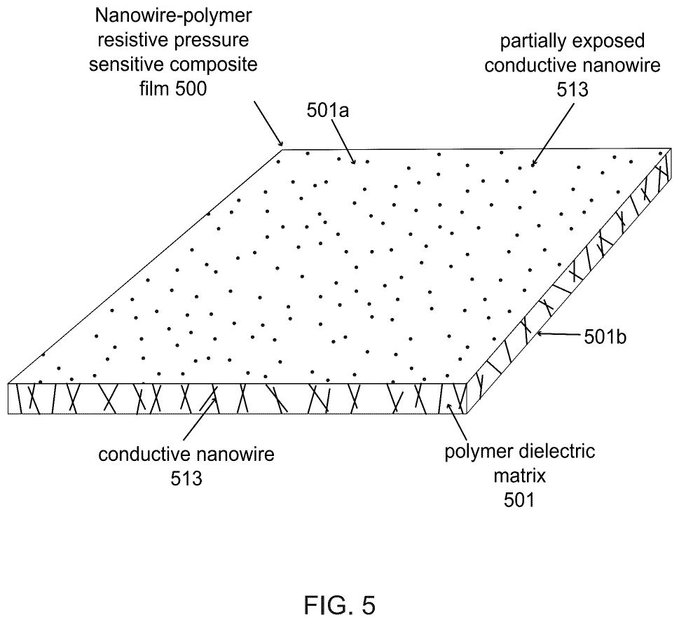

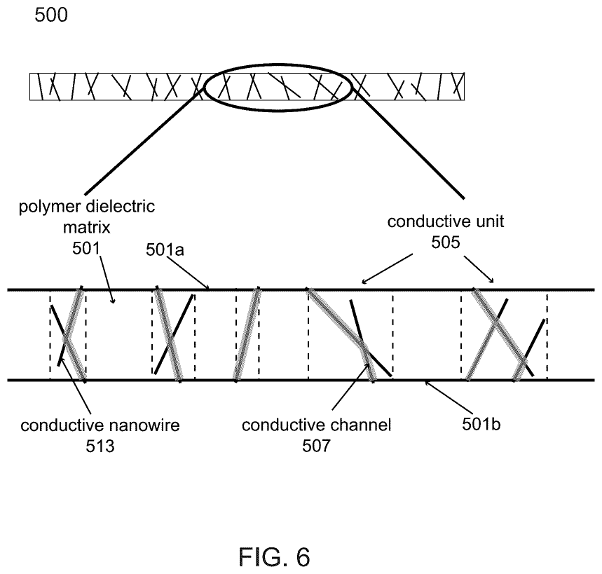

The present disclosure further provides a transparent nanowire-polymer resistive pressure-sensitive composite film comprising a transparent polymer dielectric matrix and a conductive one-dimensional nanomaterial uniformly distributed in the transparent polymer dielectric matrix and oriented substantially in a thickness direction of the nanowire-polymer resistive pressure-sensitive composite film. The transparent nanowire-polymer resistive pressure-sensitive composite film is highly transparent in the visible spectrum and made by the method described above. FIG. 5 illustrates a schematic perspective view of a transparent nanowire-polymer resistive pressure-sensitive composite film according to some embodiments of the present disclosure. FIG. 6 illustrates a partial enlarged cross-sectional view of a transparent nanowire-polymer resistive pressure-sensitive composite film according to some embodiments of the present disclosure. As shown in FIG. 5 and FIG. 6, a transparent nanowire-polymer resistive pressure-sensitive composite film 500 is provided and may comprise a transparent polymer dielectric matrix 501 and a conductive one-dimensional nanomaterial comprising conductive nanowires 513 and uniformly distributed in the transparent polymer dielectric matrix and oriented substantially in a thickness direction of the transparent nanowire-polymer resistive pressure-sensitive composite film 500.

The conductive nanowire 513 is selected from the group consisting of a metal nanowire, a conductive polymer nanowire, a ceramic conductive nanowire, a carbon nanowire, a single walled carbon nanotube, a multi-walled carbon nanotube, and a mixture thereof. In some embodiments, the conductive one-dimensional nanomaterial is a metal nanowire. The metal nanowire may include, but is not limited to, a silver nanowire (Ag nanowire), a copper nanowire, a gold nanowire, a nickel nanowire, a platinum nanowire, a stainless steel nanowire, or a mixture thereof. In one embodiment, the conductive one-dimensional nanomaterial is a silver nanowire. In some embodiments, the conductive one-dimensional nanomaterial is a single walled carbon nanotube. In some embodiments, the conductive one-dimensional nanomaterial is a multi-walled carbon nanotube. In some embodiments, the conductive one-dimensional nanomaterial is a mixture of a single walled carbon nanotube and a multi-walled carbon nanotube.

A diameter of the conductive nanowire 513 suitable for the conductive one-dimensional nanomaterial is in a range of 1 nm-100 nm. In some embodiments, a diameter of the conductive nanowire 513 suitable for the conductive one-dimensional nanomaterial is in a range 1 nm-10 nm. In some embodiments, a diameter of the conductive nanowire 513 suitable for the conductive one-dimensional nanomaterial is in a range 10 nm-50 nm. In some embodiments, a diameter of the conductive nanowire 513 suitable for the conductive one-dimensional nanomaterial is in a range 50 nm-100 nm. A length of the conductive nanowire 513 suitable for the conductive one-dimensional nanomaterial is in a range of 100% to 200% of a thickness of the transparent nanowire-polymer resistive pressure-sensitive composite film 500.

The transparent polymer dielectric matrix 501 may comprise a polymer polymerized from a liquid precursor selected from the group consisting of an acrylate, a methacrylate, an acrylic acid, a methacrylic acid, an acrylamide, a methacrylamide, a methylstyrene, a siloxane, silicone ether, an isocyanate, an epoxy, and a mixture thereof. The storage modulus of the transparent polymer dielectric matrix 501 may be in a range of 10 kPa-10 GPa, 100 kPa-10 GPa 1 MPa-10 GPa, 10 MPa-10 GPa, 100 MPa-10 GPa, 500 MPa-10 GPa, 1 GPa-10 GPa, 2 GPa-10 GPa, 3 GPa-10 GPa, 4 GPa-10 GPa, or 5 GPa-10 GPa, or any range defined between any two of the foregoing values, such as 1 MPa-500 MPa, at an ambient temperature. In some preferred embodiments, the transparent polymer dielectric matrix 501 has a storage modulus in a range of 100 kPa-100 MPa at an ambient temperature.

The transparent polymer dielectric matrix 501 of the transparent nanowire-polymer resistive pressure-sensitive composite film 500 includes a first surface 501a and a second surface 501b opposite and parallel to the first surface 501a, and the first surface 501a and the second surface 501b of the transparent polymer dielectric matrix 501 are orthogonal to the thickness direction of the transparent nanowire-polymer resistive pressure-sensitive composite film 500. Thus, the term “the conductive one-dimensional nanomaterial oriented substantially in the thickness direction of the transparent nanowire-polymer resistive pressure-sensitive composite film” used herein also means conductive one-dimensional nanomaterial oriented substantially perpendicular to the first/second surface of the transparent polymer dielectric matrix 501. The term “substantially perpendicular to” used herein means an included angle between the longitudinal axis of the conductive one-dimensional nanomaterial and a reference surface such as the first surface 501a of the transparent polymer dielectric matrix 501 is in a range of 70-90 degrees. In other words, the longitudinal axis of the conductive one-dimensional nanomaterial is oriented within 0-20 degrees of the surface normal of the first surface 501a of the transparent polymer dielectric matrix 501. In some embodiments, at least 60% of conductive nanowires 513 embedded in the transparent polymer dielectric matrix 501 are oriented substantially perpendicular to the first surface 501a of the transparent polymer dielectric matrix 501. In some embodiments, at least 70% of conductive nanowires 513 embedded in the transparent polymer dielectric matrix 501 are oriented substantially perpendicular to the first surface 501a of the transparent polymer dielectric matrix 501. In one preferred embodiment, at least 80% of conductive nanowires 513 embedded in the transparent polymer dielectric matrix 501 are oriented substantially perpendicular to the first surface 501a of the transparent polymer dielectric matrix 501.

As shown in FIG. 6, the conductive nanowires 513 embedded in the transparent polymer dielectric matrix 501 are partially exposed on the first surface 501a and/or the second surface 501b the transparent polymer dielectric matrix 501 to form non cross-talking and dispersed conductive units 505. The term “non cross-talking” used herein means that there is no electrical contact between two adjacent conductive units. Each conductive unit may comprise at least one through conductive channel 507 extending from the first surface 501a of the transparent polymer dielectric matrix 501 to the second surface 501b of the transparent polymer dielectric matrix 501 through one single conductive nanowire 513 or multiple conductive nanowires 513. The conductive units 505 have enough space between each other to ensure that the adjacent conductive units in the same area are isolated by the transparent polymer dielectric medium. Thus, the resistance is low within the conductive units 505 and extremely high between the conductive units 505, in other words, the transparent nanowire-polymer resistive pressure-sensitive composite film 500 has extremely high resistance across the first surface 501a of the transparent polymer dielectric matrix 501 and across the second surface 501b of the transparent polymer dielectric matrix 501, but low resistance within the conductive units across the transparent nanowire-polymer resistive pressure-sensitive composite film, i.e., in a thickness direction of the transparent nanowire-polymer resistive pressure-sensitive composite film 500. In some embodiments, the conductive units 505 on the first/second surfaces of the transparent polymer dielectric matrix 501 are present at a density from about 1 to 10⁵ conductive units per square microns, preferably from about 10 to 10⁵ conductive units per square microns, more preferably from about 10² to 10⁵ conductive units per square microns, even more preferably from about 10³ to 10⁵ conductive units per square microns.

The thickness of the transparent nanowire-polymer resistive pressure-sensitive composite film 500 is in a range of 0.1 microns-100 microns, preferably 1 micron-100 microns, more preferably 1 micron-50 microns, furthermore preferably 1 micron-20 microns, particularly preferably 1 micron-10 microns.

It should be noted that in the present disclosure, the first surface of the transparent polymer dielectric matrix 501 may also refer to a first surface of the transparent nanowire-polymer resistive pressure-sensitive composite film 500, and the second surface of the transparent polymer dielectric matrix 501 may also refer to a second surface of the transparent nanowire-polymer resistive pressure-sensitive composite film 500.

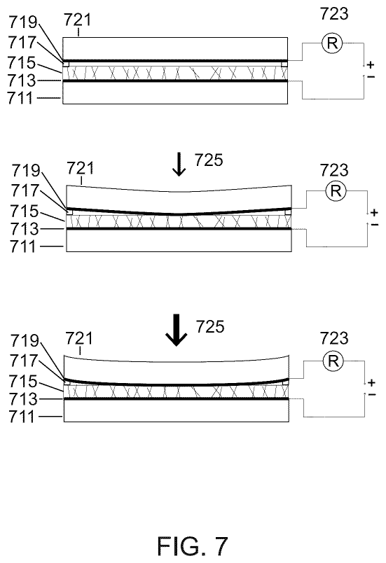

The present disclosure further provides a transparent resistive pressure sensor. FIG. 7 illustrates schematic cross-section views of a transparent resistive pressure sensor operating under different amount of compressing force according to some embodiments of the present disclosure. As shown in FIG. 7, the transparent resistive pressure sensor may include:
a flexible pressure substrate 721 and a support substrate 711, the flexible pressure substrate 721 having a pressure receiving surface and a support substrate facing surface and being parallel to the support substrate 711, the support substrate 711 having a pressure substrate facing surface;
a first electrode 719 disposed on the support substrate facing surface of the flexible pressure substrate 719 and having a support substrate facing surface;
a second electrode 713 disposed on the pressure substrate facing surface of the support substrate 711 and having a pressure substrate facing surface;
a transparent nanowire-polymer resistive pressure-sensitive composite film 715 having a first surface facing the first electrode 719 and a second surface opposite and parallel to the first surface and positioned between the first electrode 719 and second electrode 713, where the second electrode 713 is directly in electrical contact with conductive units of the transparent nanowire-polymer resistive pressure-sensitive composite film 715 through conductive nanowires partially exposed on the second surface of the transparent nanowire-polymer resistive pressure-sensitive composite film 715; and
a plurality of elastic dielectric spacers 717 configured to define an insulating gap between the first electrode 719 and the transparent nanowire-polymer resistive pressure-sensitive composite film 715.

In some embodiments, the transparent resistive pressure sensor may further include a resistance measuring circuitry 723.

The transparent nanowire-polymer resistive pressure-sensitive composite film 715 is made by the method described above. The features and the method of making of the transparent nanowire-polymer resistive pressure-sensitive composite film 715 may refer to the detailed description of the transparent nanowire-polymer resistive pressure-sensitive composite film 500 and the method of making described above, which will not be repeated herein for conciseness. In some embodiments, the transparent nanowire-polymer resistive pressure-sensitive composite film 715 may be fabricated directly on the second electrode 713 by the method of making described above. In other embodiments, the transparent nanowire-polymer resistive pressure-sensitive composite film 715 may be fabricated separately by the method of making described above and then assembled on the second electrode 713.

The flexible pressure substrate 721 may be composed of an optically transparent and flexible material selected from a polyethylene terephthalate (PET), a polyethylene naphthalate (PEN), a colorless polyimide (CPI), a polycarbonate (PC), a polymethylmethacrylate (PMMA), a polystyrene (PS), a polyethersulfone (PES), a polynorbornene (PNB), or glass. The material of the flexible pressure substrate 721 is formulated such that the flexible pressure substrate 721 has sufficient elasticity to permit it to be bent from a resting position under the force levels anticipated to be applied to the pressure receiving surface of the flexible pressure substrate 721 during use and then return to its original resting position once the force is released. The thickness of the flexible pressure substrate 721 may be in a range of 0.01 mm-2 mm. For example, in some embodiments, the flexible pressure substrate 721 may comprise a plastic film with a Young's modulus of 1 GPa-4 GPa. In some embodiments, the flexible pressure substrate 721 may be a PET substrate with the Young's modulus of 2 GPa-2.7 GPa. In some embodiments, the flexible pressure substrate 721 may be a glass sheet with a thickness of 0.01-0.33 mm

The support substrate 711 may be composed of an optically transparent material selected from a polyethylene terephthalate (PET), a polyethylene naphthalate (PEN), a colorless polyimide (CPI), a polycarbonate (PC), a polymethylmethacrylate (PMMA), a polystyrene (PS), a polyethersulfone (PES), a polynorbornene (PNB), or glass. An elasticity of the support substrate 711 is less than an elasticity of the flexible pressure substrate 721 so that the support substrate 711 does not bend when a pressure force is applied to the flexible pressure substrate 721, which facilitates the contact area between the first electrode 719 and the transparent nanowire-polymer resistive pressure-sensitive composite film 715 varying as a function of the amount of pressure force applied on the flexible pressure substrate 721. For example, when the flexible pressure substrate 721 is a plastic substrate, the support substrate 711 may be glass. When the flexible pressure substrate 721 is a thin material, the support substrate 711 may be a thicker one of the same material, such as 5-10 times thicker than the flexible pressure substrate 721, or another material with a higher Young's modulus. The thickness of the support substrate 711 may be in a range of 0.05 mm-2 mm. For instance, in one embodiment, the flexible pressure substrate 721 may comprise a plastic film with a Young's modulus of 1 GPa-4 GPa, the support substrate 711 may comprise a glass sheet with a Young's modulus of 50 GPa-90 GPa. In another embodiment, the flexible pressure substrate 721 may be a glass sheet with a thickness of 0.01 mm-0.33 mm, the support substrate 711 may comprise a glass sheet with a thickness of 1 mm-2 mm. In this way, within a defined detection range, a pressure force that bends the flexible pressure substrate will much less effect on the support substrate.

The first electrode 719 may be optically transparent and comprise a transparent conductive material selected from fluorine doped tin oxide (FTO), indium tin oxide (ITO), indium zinc oxide (IZO), indium tin zinc oxide (ITZO), poly (3,4-ethylenedioxythiophene) polystyrene sulfonate (PEDOT: PSS), carbon nanoparticles, carbon nanotubes, graphene, metal nanoparticles, metal nanowires (such as Ag nanowires), metal nano-grids, metal meshes, conductive polymer nanoparticles, conductive polymer nanopore networks, or mixtures thereof. The first electrode 719 may be directly coated on the support substrate facing surface of the flexible pressure substrate 721 by, but not limited to, slot die coating, spray coating, Meyer rod coating, blade coating, screen printing, ink jet printing, stamping, etc. The thickness of the first electrode 719 may be no more than 200 nm to ensure a high optical transparency.

In some embodiments, The first electrode 719 may further comprise a plurality of conductive traces parallel to each other and separated by an insulating gap. The pattern of the plurality of conductive traces of the first electrode 719 may be formed on the first electrode 719 by, for example, laser ablation, ion beam etching, photolithography, E-beam lithography. The width of each conductive trace is 1 mm-10 mm. The insulating gap between two adjacent conductive traces has a width of 0.1 mm-0.5 mm. The plurality of conductive traces of the electrode 719 are extended along a first direction and parallel the first direction.

Similarly, the second electrode 713 may be optically transparent and comprise a transparent conductive material selected from fluorine doped tin oxide (FTO), indium tin oxide (ITO), indium zinc oxide (IZO), indium tin zinc oxide (ITZO), poly (3,4-ethylenedioxythiophene) polystyrene sulfonate (PEDOT: PSS), carbon nanoparticles, carbon nanotubes, graphene, metal nanoparticles, metal nanowires (such as Ag nanowires), metal nano-grids, metal meshes, conductive polymer nanoparticles, conductive polymer nanopore networks, or mixtures thereof. The second electrode 713 may be directly coated on the pressure substrate facing surface of the support substrate 711 by, but not limited to, slot die coating, spray coating, Meyer rod coating, blade coating, screen printing, ink jet printing, stamping, etc. The thickness of the second electrode 713 may be no more than 200 nm to ensure a high optical transparency.

The second electrode 713 may comprise a plurality of conductive traces parallel to each other and separated by an insulating gap. The pattern of the plurality of conductive traces of the second electrode 713 may be formed on the second electrode 713 by, for example, laser ablation, ion beam etching, photolithography, E-beam lithography. The width of each conductive trace is 1 mm-10 mm. The insulating gap between two adjacent conductive traces has a width of 0.1 mm-0.5 mm. The plurality of conductive traces of the second electrode 713 are extended along a second direction and parallel the second direction, where the first direction is different from the direction.

The plurality of conductive traces of the first electrode 719 and the plurality of conductive traces of the second electrode 713 are oriented at an angle to define a plurality of pressure sensing pixels at cross sections of the plurality of conductive traces of the first electrode 719 and the plurality of conductive traces of the second electrode 713, i.e., the first direction and the second direction are different and oriented at the angle. In some embodiments, the plurality of conductive traces of the first electrode 719 are oriented substantially perpendicular to the plurality of conductive traces of the second electrode 713. Each pressure sensing pixel may comprise at least one conductive unit of the transparent nanowire-polymer resistive pressure-sensitive composite film described above. It is understandable to those skilled in the art that the plurality of conductive traces of the first electrode 719 and the plurality of conductive traces of the second electrode 713 are connected to an external resistance measuring circuitry comprising a multiplexer and a control circuitry to detect a resistance change of each pressure sensing pixel when an external force is exerted on the transparent resistive pressure sensor and a location where the external force is exerted on the transparent resistive pressure sensor during use.

The plurality of elastic dielectric spacers 717 are separate, optically transparent and arranged between the first electrode 719 and the transparent nanowire-polymer resistive pressure-sensitive composite film 715 for connecting the flexible pressure substrate 721 and the support substrate 711 together and providing structural support for an insulating gap formed between the first electrode 719 and the transparent nanowire-polymer resistive pressure-sensitive composite film 715. The elastic dielectric spacers 717 may comprise a dielectric elastomer such as an acrylic elastomer, a polyurethane elastomer, a silicone elastomer, etc. The elastic dielectric spacers 717 may be a pillar shape with a diameter of 15 microns-100 microns and a height of 1 micron-100 microns. The size, shape, and stiffness of the elastic dielectric spacers 717 may vary according to the elasticity of the flexible pressure substrate 719 and actual applications. The cross section of the elastic dielectric spacers 717 projected on a x-y plane, i.e., a plane parallel to the first surface of the transparent nanowire-polymer resistive pressure sensitive composite film 715, may include, but is not limited to, a circle, an ellipse, a ring, a square, a rectangle, or a regular polygon. The insulating gap may include, but is not limited to, an insulating gas such as nitrogen or air, or a non-volatile insulating fluid such as ethylene glycol, silicone oil, or mineral oil, etc.

When no pressure force is applied to the flexible pressure substrate 721 of the transparent resistive pressure sensor, as shown in the upper panel of FIG. 7, there is an open circuit between the first electrode 719 and the second electrode 713, and a resistance measuring circuitry 723 cannot detect the resistance due to the open circuit. When a pressure force 725 is applied to the flexible pressure substrate 721, as shown in the middle panel of FIG. 7, the flexible pressure substrate 721 bends downward, and the first electrode 719 contacts the first surface of the transparent nanowire-polymer resistive pressure-sensitive composite film 715, and at least one conductive unit of the transparent nanowire-polymer resistive pressure-sensitive composite film 715 and the first electrode 719 are in electrical contact through conductive nanowires of the at least one conductive unit partially exposed on the first surface of the transparent nanowire-polymer resistive pressure-sensitive composite film 715. As a result, at least one conductive channel is connected between the first electrode 719 and the second electrode 713, and the resistance measuring circuitry 723 may detect the local resistance of the pressure area where the pressure force is applied. When the applied pressure force 725 increases, as shown in the lower panel of FIG. 7, the contact area of the first electrode 719 and the transparent nanowire-polymer resistive pressure-sensitive composite film 715 on the first surface of the transparent nanowire-polymer resistive pressure-sensitive composite film 715 increases, the first electrode 719 makes electrical contact with more conductive units of the transparent nanowire-polymer resistive pressure-sensitive composite 715, more conductive channels are connected between the first electrode 719 and the second electrode 713, and the resistance detected by the resistance measuring circuitry 723 decreases. When the applied pressure force 725 is removed (not shown), the flexible pressure substrate 721 returns to its original position, i.e., the resting position, the electrical contact between the first electrode 719 and the transparent nanowire-polymer resistive pressure-sensitive composite film 715 is disconnected, and the open circuit state is restored between the first electrode 719 and the second electrode 713.

The conductive channel of traditional pressure-sensitive composites in the art is composed of conductive particle chains dispersed in a dielectric matrix. The concentration of conductive particles must be higher than the percolation threshold to form a continuous conductive channel, which may significantly reduce the optical transparency of the composite due to the light scattering of conductive particles. On the contrary, the first and second surfaces of the transparent nanowire-polymer resistive pressure-sensitive composite film provided by the present disclosure are basically connected through conductive nanowires in the length direction of the conductive nanowires, so only a small number of conductive nanowires are needed to achieve the effect of low resistance, which ensures the high optical transmittance of the transparent nanowire-polymer resistive pressure-sensitive composite film.

Traditional pressure-sensitive composites change the spatial arrangement of conductive particles in the dielectric matrix by compression, so as to change the conduction between conductive particles and thus the resistance. The transparent nanowire-polymer resistive pressure-sensitive composite film provided by the present disclosure activates different numbers of conductive units by changing the contact area between the electrode and the surface of the transparent nanowire-polymer resistive pressure-sensitive composite film, so as to change the measured resistance across the transparent nanowire-polymer resistive pressure-sensitive composite film. In a using process, the transparent nanowire-polymer resistive pressure sensitive composite film of the transparent resistive pressure sensor of the present disclosure does not need to be repeatedly deformed, and the conductive nanowires do not need to be repeatedly displaced in the polymer dielectric matrix, which ensures the durability of the transparent nanowire-polymer resistive pressure-sensitive composite film. In traditional pressure-sensitive composites, conductive particles are crosslinked to form conductive particle chains. When pressed, the spatial arrangement of conductive particle chains changes, resulting in the change of the overall resistivity of the composite. The conductive units in the transparent nanowire-polymer resistive pressure-sensitive composite film provided by the present disclosure are dispersed and discrete, and the locally applied pressure will not affect the detection resistance of other areas. Therefore, the transparent resistive pressure sensor of the present disclosure may be utilized in an electronic system with conventional multi-point touch detection hardware and software to detect and process multi-point touch and the amount of applied pressure at different positions at the same time. In a preferred embodiment, since the transparent resistive pressure sensor is optically transparent in the visible spectrum, it can be combined with a visual display device. Of course, in other embodiments, the transparent resistive pressure sensor of the present disclosure may be incorporated into other systems or devices that do not require transparency.

It should be noted that the above embodiments/examples are only used to illustrate the technical features of the present disclosure, not to limit them; although the present disclosure has been described in detail with reference to the foregoing embodiments and examples, those of ordinary skill in the art should understand that: the technical features disclosed in the foregoing embodiments and examples can still be modified, some or all of the technical features can be equivalently replaced, but, these modifications or replacements do not deviate from the spirit and scope of the disclosure.

What is claimed is:

1. A method of making a nanowire-polymer resistive pressure-sensitive composite film comprising a transparent polymer dielectric matrix and a conductive one-dimensional nanomaterial uniformly distributed in the transparent polymer dielectric matrix and oriented substantially in a thickness direction of the nanowire-polymer resistive pressure-sensitive composite film, the method comprising:
providing a synthetic substrate coated with a release layer thereon and providing a polymer precursor solution comprising a liquid precursor of the transparent polymer dielectric matrix and optionally a first volatile solvent;
coating the polymer precursor solution on the release layer at room temperature to obtain a liquid precursor film on the release layer by using the polymer precursor solution;
heating the liquid precursor film to a first temperature, wherein the first temperature is lower than a boiling point of the liquid precursor of the transparent polymer dielectric matrix and a polymerization temperature of the liquid precursor of the transparent polymer dielectric matrix if the liquid precursor of the transparent polymer dielectric matrix is thermally polymerizable;
spraying vertically and uniformly a conductive nanowire suspension comprising the conductive one-dimensional nanomaterial and a second volatile solvent onto the liquid precursor film to obtain a liquid precursor film embedded with the conductive one-dimensional nanomaterial that is oriented substantially in a thickness direction of the liquid precursor film, wherein a boiling point of the second volatile solvent is lower than the first temperature; and
in-situ polymerizing and curing the liquid precursor film embedded with the conductive one-dimensional nanomaterial by heating the liquid precursor film embedded with the conductive one-dimensional nanomaterial to a second temperature or irradiating the liquid precursor film embedded with the conductive one-dimensional nanomaterial with UV light to obtain a cured liquid precursor film embedded with the conductive one-dimensional nanomaterial, wherein the second temperature is higher than the polymerization temperature of the liquid precursor of the transparent polymer dielectric matrix if the liquid precursor of the transparent polymer dielectric matrix is thermally polymerizable.

2. The method of claim 1, further comprising:
removing the cured liquid precursor film embedded with the conductive one-dimensional nanomaterial from the synthetic substrate to obtain the nanowire-polymer resistive pressure-sensitive composite film comprising the conductive one-dimensional nanomaterial oriented substantially in a thickness direction of the nanowire-polymer resistive pressure-sensitive composite film.

3. The method of claim 1, wherein the spraying vertically and uniformly the conductive nanowire suspension onto the liquid precursor film comprises maintaining a spray nozzle perpendicular to a surface of the liquid precursor film that faces the spray nozzle during spraying.

4. The method of claim 3, wherein the spraying further comprises adjusting a spraying distance between the spray nozzle and the surface of the liquid precursor film, a size of the spray nozzle, a spraying angle, and a spraying pressure.

5. The method of claim 1, wherein the liquid precursor is selected from the group consisting of an acrylate, a methacrylate, an acrylic acid, a methacrylic acid, an acrylamide, a methacrylamide, a methylstyrene, a siloxane, a silicone ether, an isocyanate, an epoxy, an oligomer thereof, a prepolymer thereof, and a mixture thereof.

6. The method of claim 2, wherein the conductive one-dimensional nanomaterial comprises conductive nanowires selected from the group consisting of a metal nanowire, a conductive polymer nanowire, a ceramic conductive nanowire, a carbon nanowire, a single walled carbon nanotube, a multi-walled carbon nanotube, and a mixture thereof.

7. The method of claim 6, wherein a thickness of the nanowire-polymer resistive pressure-sensitive composite film is in a range of 0.1-100 microns.

8. The method of claim 7, wherein a length of the conductive nanowire is in a range of 100% to 200% of the thickness of the nanowire-polymer resistive pressure-sensitive composite film.

9. The method of claim 8, wherein a diameter of the conductive nanowire is in a range of 1 nm-100 nm.

10. The method of claim 9, wherein the transparent polymer dielectric matrix formed of the cured liquid precursor film has a storage modulus of 10 kPa-10 GPa at an ambient temperature.

11. The method of claim 10, wherein the conductive nanowires are uniformly distributed in the transparent polymer dielectric matrix and partially exposed on a first surface and/or a second surface of the transparent polymer dielectric matrix to form non cross-talking and dispersed conductive units, wherein the first surface and second surface of the transparent polymer dielectric matrix are opposite and parallel to each other and are orthogonal to the thickness direction of the transparent nanowire-polymer resistive pressure-sensitive composite film, and each conductive unit comprises at least one through electrically conductive channel extending from the first surface to the second surface of the transparent polymer dielectric matrix through one single conductive nanowire or multiple conductive nanowires.

12. The method of claim 11, wherein a viscosity of the liquid precursor is in a range of 0.5-2000 cP.

13. The method of claim 4, wherein the spraying distance is in a range of 1 cm-20 cm, the size of spray nozzle is in a range of 0.01 mm-1 mm, the spraying angle is equal to or less than 40 degrees, and the spraying pressure is in a range of 14.7 psi-80 psi.

14. The method of claim 1, wherein a mass ratio of the conductive one-dimensional nanomaterial to the second volatile solvent is 0.005-0.05 wt %.

15. The method of claim 1, wherein the first volatile solvent and the second volatile solvent is the same as or different from each other and independently comprise one or more of water, a volatile alcohol, a volatile ether, tetrahydrofuran, dioxane, a volatile ketone, or a volatile ester.

16. The method of claim 6, wherein the conductive one-dimensional nanomaterial is a metal nanowire.

17. The method of claim 6, wherein the conductive one-dimensional nanomaterial is a silver nanowire.

18. The method of claim 6, wherein the conductive one-dimensional nanomaterial is a single-walled carbon nanotube, a multi-walled carbon nanotube, or a mixture thereof.

19. A transparent nanowire-polymer resistive pressure-sensitive composite film comprising a transparent polymer dielectric matrix and a conductive one-dimensional nanomaterial uniformly distributed in the transparent polymer dielectric matrix and oriented substantially in a thickness direction of the transparent nanowire-polymer resistive pressure-sensitive composite film, wherein the conductive one-dimensional nanomaterial comprises conductive nanowires selected from the group consisting of a metal nanowire, a conductive polymer nanowire, a ceramic conductive nanowire, a carbon nanowire, a single walled carbon nanotube, a multi-walled carbon nanotube, and a mixture thereof, and wherein the conductive nanowires are uniformly distributed in the transparent polymer dielectric matrix and partially exposed on a first surface and/or a second surface of the transparent polymer dielectric matrix to form non cross-talking and dispersed conductive units, wherein the first surface and second surface of the transparent polymer dielectric matrix are opposite and parallel to each other and are orthogonal to the thickness direction of the transparent nanowire-polymer resistive pressure-sensitive composite film, and each conductive unit comprises at least one through electrically conductive channel extending from the first surface to the second surface of the transparent polymer dielectric matrix through one single conductive nanowire or multiple conductive nanowires.

20. A transparent resistive pressure sensor comprising the transparent nanowire-polymer resistive pressure-sensitive composite film of claim 19.
